(19) United States
(12) Patent Application Publication
(10) Pub. No.: US 2023/0097276 A1
(43) Pub. Date: Mar. 30, 2023

(54) APPARATUS AND PROCESS WITH A DC-PULSED CATHODE ARRAY

(71) Applicant: EVATEC AG, Trübbach (CH)

(72) Inventors: Mohamed ELGHAZZALI, Feldkirch (AT); Oliver RATTUNDE, Grabs (CH); Christian EGLI, Sevelen (CH)

(21) Appl. No.: 17/905,976

(22) PCT Filed: Feb. 1, 2021
(86) PCT No.: PCT/EP2021/052305

§ 371 Date: Sep. 9, 2022

(30) Foreign Application Priority Data
Mar. 13, 2020 (CH) 00291/20

(51) Int. Cl. C23C 14/34; H01J 37/34; C23C 14/35; C23C 14/14

(52) U.S. Cl. CPC C23C 14/3407; H01J 37/3455; C23C 14/352; C23C 14/3485; C23C 14/14

(57) ABSTRACT

An apparatus for sputter deposition of material on a substrate. The apparatus includes a deposition chamber and a cathode array mounted in the deposition chamber. The array has three or more rotating cathodes. Each cathode has a cylindric target of equal target length L_{T} and a magnetic system. The cathodes are spaced from one another such that their longitudinal axes Y_{Cj} are arranged parallel to each other, in a distance T_{SD} from a substrate plane S, and spaced apart along a projection of a substrate axis X in a distance T_{TT}, whereat each cathode of the cathode array includes a magnetic system. The magnetic system of at least one cathode is swivel mounted round respective cathode axis Y_{Cj} to swivel the magnetic system into and out of a swivel plane P_{TS}. A pedestal is designed to support at least one substrate of maximal dimensions x*y to be coated in a static way. The pedestal is positioned in the deposition chamber in front of and centered with reference to the cathode array. At least one pulsed power supply is configured for supplying and controlling a power to at least one of the cathodes.

The invention refers to an apparatus comprising a DC-pulsed cathode array according to claim 1 and to a process to deposit a coating with a respective apparatus according to claim 18.

### TECHNICAL BACKGROUND

While use of rotating-cathode arrays is widespread with pass-through vacuum deposition plants for large area coatings as for instance in the glass coating industries, high quality coating equipment and processes for layer deposition on static substrates, e.g. in the flat panel industry, still needs improvement in terms of uniformity of the coatings and/or productivity of the equipment used. One main reason is the occurrence of a swing induced thickness asymmetry in diagonally opposed deposition areas with reference to a cathode axis Y_{Cj} when two or more neighboring targets of a cathode array are operated with swivel mounted magnet systems to improve deposition uniformity under and between rotating cathodes along a central area on both sides of substrate axis X normal to Y_{Cj}. This makes it necessary to provide a considerably higher volume of the deposition chamber to be used than necessary with comparable two-dimensional planar magnetron configurations. Due to non-uniformity issues arisen by that effect, as discussed in detail with FIG. 3 and below, state of the art equipment has to provide a cathode area protruding the usable coating area for at least twofold the substrate to target distance at each side of the cathode axes. Therefore, this effect drastically diminishes productivity gains of rotary cathodes when it comes to the coating of relatively small display areas, e.g. smaller or equal of about 1 m².

### DEFINITIONS

A (maximum) swivel angle ±β here defines the maximum angular deflection of a swivel mounted magnetic system out of a swivel plane P_{TS} defining the middle or center of the overall deflection. The overall deflection is defined by the total swivel angle 2 β. A swivel plane of target n comprises respective cathode axis Y_{Cj} and forms an angle α with the substrate plane S. During a sputter deposition process the magnetic system is moved from one extreme position to the other, i.e. from +β to −β or reverse. This can be effected once or repeatedly in a constant or stepwise manner. Note that speed may vary with time or the hold time can be different for every step, where each step refers to a different position of the magnetic system, so that dwell time of the magnetic system can be different for the positive and the negative angle-sector (i.e. +β to zero and −β to zero, where zero defines the position of the swivel plane which can be pivoted or non-pivoted from a zero position of the magnetic system which is in opposition to the substrate plane S).

An essentially equidistant distance T_{SD} of the outer target diameter to the substrate surface in the following means that each shortest distance T_{SD1} to T_{SDn} of the outer target diameter DT of the n-cathodes to the substrate plane S does not deviate from a mean value MT_{SD}={Σₖ₌₁ⁿT_{SDk}}n⁻¹ more than two millimeters, therewith for each T_{SD1} to T_{SDn} the following applies: (MT_{SD}−2 mm)≤T_{SKs=1 . . . n}≤(MT_{SD}+2 mm).

This can be seen as the maximum difference allowable at the end of target life, whereas with an all new targets configuration the difference will be essentially smaller, e.g. about zero millimeters. This refers at least to all targets driven with pulsed DC-sources and swivel angle β>0.

The substrate plane S is defined by the surface of a flat substrate, e.g. a wafer, which can be mounted to the substrate pedestal. The plane itself however extends over the limited extension of the substrate surface.

A normal distance T_{SC} or T_{SD} between a longitudinal axis of the cathode or an outer target diameter and the substrate plane S is the shortest distance between the respective longitudinal axis Y_{Cj} or the respective outer target diameter D_{Tk} and the substrate plane.

A pedestal is a substrate support designed to support an essentially flat substrate of maximal dimensions x*y (x times y) or smaller. To support a substrate in a static way means the pedestal is designed to hold a substrate in such a way that it is not moved during a deposition process.

A bipolar pulsed or a bipolar power supply means a power supply which can provide at least a voltage reversal, e.g. after each negative pulse a relative short positive pulse or spike follows to clear potentially damaging charge buildup, thereby reducing or avoiding incidence of electric arcs. Although such pulses sequences will be seen as the standard sequence in the following, alternatively, bipolar pulses of different asymmetric or symmetric pulse patterns, with or without offset-time (pause) between pulse-cycles can be used up to different process needs.

The use of the terms inward and outward refers to directions towards and away from a center plane YZ, according to the figures. Center plane YZ usually is a symmetry plane of the cathode array.

The use of the terms up, upwards and down, downwards or lower and higher or the like refers to the Z-axis according to the drawings as shown in the figures but not mandatory to a possible direction of a cathode or substrate when mounted. Both can be mounted also in various different positions of a vacuum chamber, e.g. on a top, on a bottom, or a sidewall of the vacuum chamber however will be always mounted in a position essentially facing each other, e.g. top versus bottom or on two opposite sides of the chamber.

### SUMMARY OF THE INVENTION

It has been found that drawbacks of state of the art apparatuses can be essentially diminished by the use of an apparatus according to claim 1 or by applying a process according to claim 18. Surprisingly the relative usable coating area of cathode arrays can be remarkable extended together with an efficient improvement of uniformity issues, e.g. with reference to the thickness of the coatings.

In a first embodiment of the invention an apparatus for sputter deposition of material on a substrate comprises:
a deposition chamber;
a cathode array mounted in the deposition chamber, said array having three or more rotating cathodes, each cathode having a cylindric target of equal target length L_{T} and a magnetic system, the cathodes being spaced from one another such that their longitudinal axes Y_{Cj} are arranged parallel to each other, in a normal distance T_{SC} from a substrate plane S, and spaced apart along a projection of a substrate axis X in a distance T_{TT}, whereat each cathode of the cathode array comprises a magnetic system and the magnetic system of at least one cathode is swivel mounted round and in a distance to the respective cathode axis Y_{Cj} to swivel the magnetic system into and out of a swivel plane P_{TS}, the latter comprising the center of the cathode axis Y_{Cj} and being directed towards the substrate plane S, the swivel movement of the magnetic system being independent from the rotation of the targets;
a pedestal designed to support at least one substrate of maximal dimensions x*y to be coated in a static way; which means that the pedestal is designed to hold the substrate statically, which therefore does not change its position during sputtering, e.g. with reference to the apparatus and its components like the position of the sputtering cathodes; the pedestal being positioned in the deposition chamber in front of and centered with reference to the cathode array, whereat x is in parallel to axis X, y is in parallel to axis Y, both axis X and Y are normal to each other, and longitudinal cathode axes Y_{Cj} are in parallel to axis Y. The center of the X/Y coordinates also defines the center of the target plane S. Maximal dimensions of the surface to be coated x*y will usually also apply to support boundaries of the pedestal, which can be a holding frame, can be formed as a recess, and/or may comprise or consist of clamps or an ESC to center and or fix the substrate. Such apparatuses will be especially adapted for medium to small substrate dimensions, e.g. of dimensions x*y with y 1000 mm or smaller, or even equal or smaller to 700 mm, depending on the target length T_{L}, respectively the active target length T_{LA} and respective smallest target protrusion over the substrate surface as possible, whereas x depends primarily on the number and diameter of the cathodes to be used. Usually x and y will be of similar or essentially the same dimensions. However, with given minimum target protrusion, bigger or smaller dimensions of one side can be realized by respective target length and or number of cathodes, see also below; It should be mentioned that substrate dimensions include the maximal substrate dimensions and any smaller dimensions, whereby the maximum substrate dimensions also relates to the maximum dimensions of the support boundary;
at least one pulsed power supply configured for supplying and controlling a power to at least one of the cathodes whereat the same or alternatively a power which is different or variable from the power supplied to the other cathodes can be applied to at least one of the cathodes.

In a further embodiment of the apparatus the following applies to a maximum substrate or a maximum support boundary dimension yₘₐₓ which is parallel to longitudinal axes Y:

(T_{LA}−3.9 MT_{SD})≥yₘₐₓ≥(T_{LA}−2 MT_{SD})

Especially (T_{LA}−3.5 MT_{SC})≥yₘₐₓ(T_{LA}−2.5 MT_{SD}) whereat T_{LA} is the length of an active region on the target surface, MT_{SD} is the mean shortest distance between the outer target diameter D_{Tn} and the substrate plane S. As an example the maximum substrate/boundary dimensions can be yₘₐₓ=T_{LA-}3 MT_{SD}. This means that the targets protrusion at each “y”-side of the x*y-plane can be as small as about the 1.5-fold of the distance MT_{SD} between the target plan S and the outer diameter of the target(s) D_{T} or M_{Tn}. The latter referring to the mean outer diameter of the target(s) driven with a pulsed power supply and a swivel angle β>0. This however is essentially smaller than any state-of-the-art protrusions needed for sputtering on stationary substrates which usually need at least a fourfold protrusion of the targets to avoid swing induced thickness asymmetry.

It should be mentioned that a geometric target length can be about the same or bigger than the active target length, that is T_{LA}≈T_{L} or T_{LA}≤T_{L}, whereat T_{L} stands for the total target length.

The mean value MT_{SD} may correspond approximately or exactly to the values of the particular distance values T_{SDk=1} . . . T_{SDn} between the respective outer target diameter and the target plane, i.e. MT_{SD}≈T_{SDk=}1 . . . ≈T_{SDn} and therewith fall under the definition of an essentially equidistant distance T_{SD}, see above with definitions. Therewith the outer target diameters D_{T} are arranged essentially equidistant in a normal distance T_{SD} from a substrate plane S. This will be the case when all targets are new or even at the end of the target life as long as all targets are made of the same material and essentially driven with the same power, which is favorably with reference to process efficiency.

In a further embodiment the distance T_{TT} between the axes of neighboring cathodes or electrodes is equal for all distances T_{TTk-n} between neighboring cathodes or electrodes, e.g. in a plane in parallel to the substrate plane S.

In a further embodiment of the invention the cathodes may be spaced equidistantly in a distance T_{SC} from the substrate plane S.

In a further embodiment distance T_{SCo} of at least one or both outer cathodes to the target plane S can be different to the distance T_{SCi} of the inner cathodes to the target plane S.

An angle α between swivel plane PTs and the substrate plane S may be defined by: 40°≤α≤100°.

For a maximum swivel angle β of the at least one swivel mounted magnetic system the following applies: 0°≤|β|≤80°, e.g. 20°≤|ββ≤70°, whereas values near the higher limits apply to an a near or at 90°. The maximum swivel angle β thereby defines a maximal deviation of the magnetic system out of the swivel plane PTs. An alignment of the magnet system towards a neighboring cathode should be avoided for obvious reasons. That means that swivel angles ±β as any swivel angles between should be in line of sight with the substrate plane S without intersecting a neighboring cathode.

In a preferred embodiment the outer swivel plane P_{TSo} will be inclined to the substrate plane S in an angle αₒ=50±10°. It should be noted that the inclination of the outer swivel planes P_{TSo} will be always directed towards the substrate plane S and towards the central plane YZ, that is inwards directed. Therewith the maximum swivel angle βₒ of the two outer cathodes can be chosen from 30° to 50°, that is 30°≥|βₒ|≤50°, e.g. βₒ=±40° from the swivel plane P_{Tso}, or a total swivel angle 2βₒ=80°. In this case the inner swivel plane P_{TSi} could be inclined to the substrate plane S in an angle αᵢ=90±10° with a maximum swivel angle βᵢ of the inner magnet systems of 50°≥|βᵢ|≤70°, e.g. βᵢ=±60° referring to a total swivel angle 2βᵢ=120°.

In a further embodiment the pulsed power supply can be a bipolar pulsed power supply. The bipolar pulsed power supply may be configured as a dual magnetron supply, the outputs of different polarity being electrically connected with the inputs of two neighboring cathodes, here named electrodes, as in this case the neighboring electrodes act alternatingly as cathode and anode.

Each cathode of the cathode array can be connected to a dedicated pulsed power supply, e.g. bipolar, or to a dual magnetron supply. As an example with a four cathodes array the inner cathodes may be connected to the opposite polarities of a dual magnetron supply. Due to the alternating nature of their polarity these cathodes are referred to as electrodes. At the same time the outer cathodes can be connected to dedicated bipolar pulsed DC-supplies. The dual magnetron supply being synchronized with the dedicated bipolar power supplies. For further examples see FIG. 1 and FIG. 2 and respective description. As far as more than one pulsed power supply is used, the power supplies will be connected to a pulse synchronizing unit, e.g. to clock the pulses synchronously.

In a further embodiment least one or both outer power supplies may be DC supplies.

The pedestal can be electrically isolated to hold the substrate on a floating potential during the deposition process, alternatively the pedestal can be electrically grounded.

Usually an inventive apparatus may comprise a gas distribution system for providing one or more process gases. The anode may be a ground anode formed by the process chamber and may comprise also respective electrically connected elements like shieldings, liners or similar.

The invention also refers to a process to deposit a coating comprising the use of an inventive apparatus as described above, whereat a substrate is mounted to and positioned with the pedestal in the deposition chamber. When vacuum has been applied to the deposition chamber and a process gas introduced to the chamber, e.g. until a reference pressure has been reached, deposition of a coating on at least one flat substrate within the dimensions x*y in the target plane S is started by applying a pulsed target power to at least one cathode of the array.

By applying inventive processes a coating thickness uniformity unif_{T} within the substrate dimensions x*y of unif_{T}≤5% can be produced. Where uniformity is defined as

unif=(Max−Min)/(2*Mean)

with Max and Min being the respective highest and lowest value measured.

Each cathode may be driven by a separate power supply which can be all pulsed power supplies or a combination of at least one pulsed power supply, e.g. for the inner cathode(s), and DC supplies, e.g. for the outer cathodes.

At least one power supply may be a bipolar power supply.

In a further embodiment two neighboring cathodes, here electrodes can be driven by a bipolar power supply in a dual magnetron configuration with an output of different polarity connected to each neighboring electrode. As an example, the inner cathodes of a four cathodes array or alternatively the right and the left cathode pair of such an array can be driven by a respective bipolar power supply in a dual magnetron configuration.

Using inventive processes as described also Chrome (Cr), copper (Cu), tantalum (Ta), titanium (Ti), tungsten (W), tungsten titanium (WTi) coatings, where a strong expression of swing induced thickness asymmetry has been observed with state of the art processes and equipment, can be deposited with Cr, Cu, Ta, Ti, W, WTi targets having a reduced sidewise protrusion over the substrate surface.

The pedestal can be mounted electrically floating, electrically grounded, or on a defined bias potential given by a bias generator which can supply an RF-voltage.

The invention is further directed to the use of an inventive apparatus or process to manufacture a product comprising a coating having a uniformity unif_{R} of the specific resistance R [Ωm] of unif_{R}≤5% and/or a thickness uniformity unif_{T}≤5% within the substrate dimensions x*y.

It should be mentioned that two or more embodiments of the apparatus according to the invention may be combined unless being in contradiction. Which means that all features as shown or discussed in connection with only one of the embodiments or examples of the present invention and not further discussed with other embodiments or examples can be seen to be features well adapted to improve the performance of other embodiments of the present invention too, as long such a combination cannot be immediately recognized as being prima facie inexpedient for the man of art, as for instance using a ground and floating bias at the same time or similar. Therefor with exceptions as mentioned all combinations of features of certain embodiments or examples can be combined with other embodiments or examples even when such features are not mentioned explicitly.

### FIGURES

The invention shall now be further exemplified with the help of figures. Figures are drawn exemplarily for mere demonstrative purposes only and therefore do not show actual equipment dimensions, nor do they show details known to the man of art but not essential for the understanding of the present invention. Same numbers and reference signs refer to same features also with different figures. Apostrophes and subscripted indices “i” for features of an inner cathode, and “o”, for features of an outer cathode, or numbers refer to alternatives or specific features of a specific cathode. The figures show:

FIG. 1: apparatus vertical projection

FIG. 2: apparatus horizontal projection

FIG. 3: deposition in substrate plane S

FIG. 4: cathode side view

FIG. 5: thickness distribution along X-coordinate

FIG. 6: pulse scheme (bi-polar)

FIG. 7: pulse scheme (dual magnetron)

FIG. 8: simulated thickness scheme

FIG. 9: thickness distributions along y-coordinate (DC)

FIG. 10: relative thickness along y-coordinate (DC)

FIG. 11: relative thickness along y-coordinate (pulsed)

FIG. 12: surface scan thickness distribution (DC)

FIG. 13: surface scan thickness distribution (pulsed)

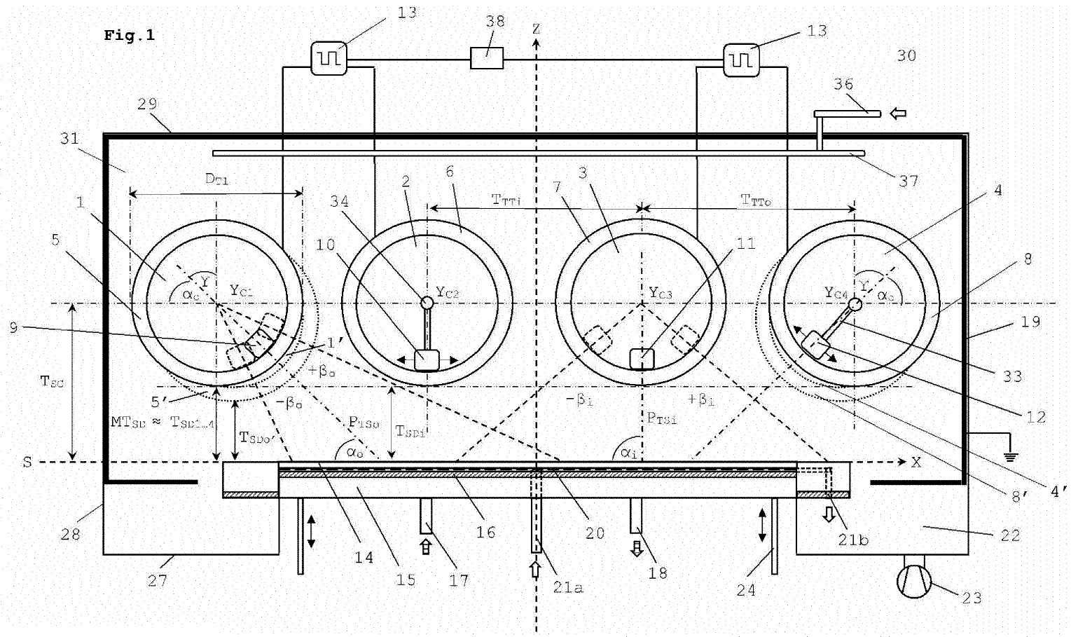

FIG. 1 is a vertical projection along central axes X and Z of an inventive apparatus 30 comprising a four cathodes 1,2,3,4 array. The cathodes being equipped with rotating targets 5,6,7,8 and swivel mounted magnetic systems 9,10,11,12, both moving round respective longitudinal axes Y_{C1},Y_{C2},Y_{C3},Y_{C4} of the cathodes. Magnetic systems 10 and 11 are shown in a facing position to the substrate surface or substrate plane S, whereas magnetic systems 9 and 12 are swiveled towards the center, with all magnetic systems shown as positioned within their respective swivel plane P_{TS} defining the center of a respective total swivel angle 2β, e.g. for the swivel angles of the inner cathodes, here with an angle αᵢ=90° between a swivel plane P_{TSi} of an inner cathode 2,3 and the substrate plane S, 2βᵢ=|+βᵢ|+|−βᵢ| and |−βᵢ|=|+βᵢ|, the same is valid for ±βₒ, here with an angle αₒ=45° between the swivel plane P_{TSo} of an outer cathode 1,4 and the substrate plane S. With such a configuration outer and inner swivel angles will be usually different, e.g. βₒ<βᵢ, to avoid positions where magnetic systems might face the next neighboring cathode and mutual cathode deposition would take place.

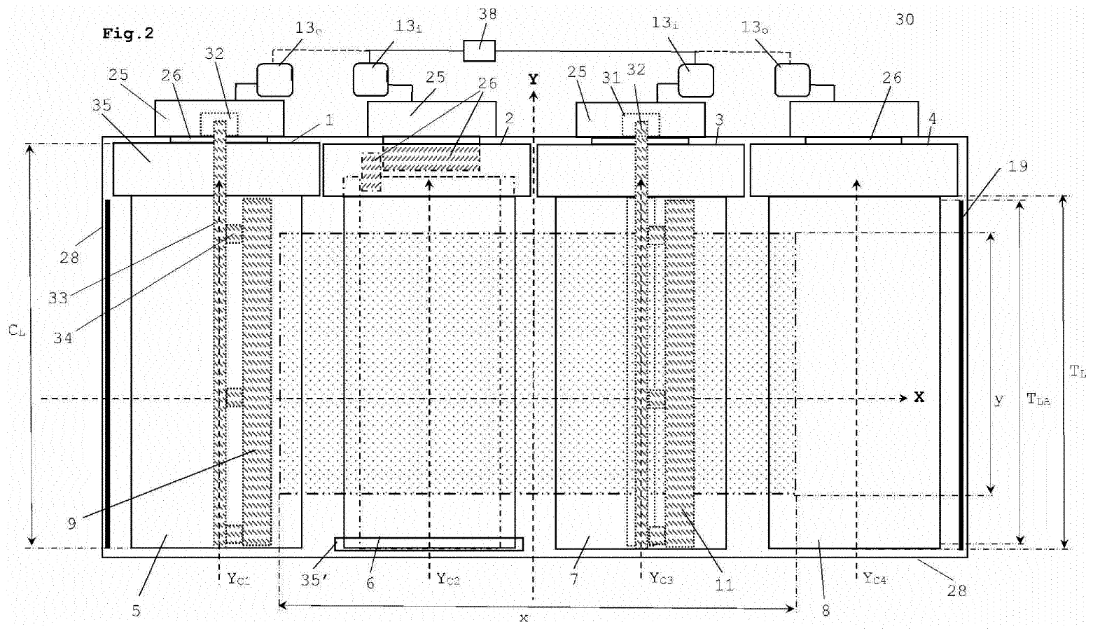

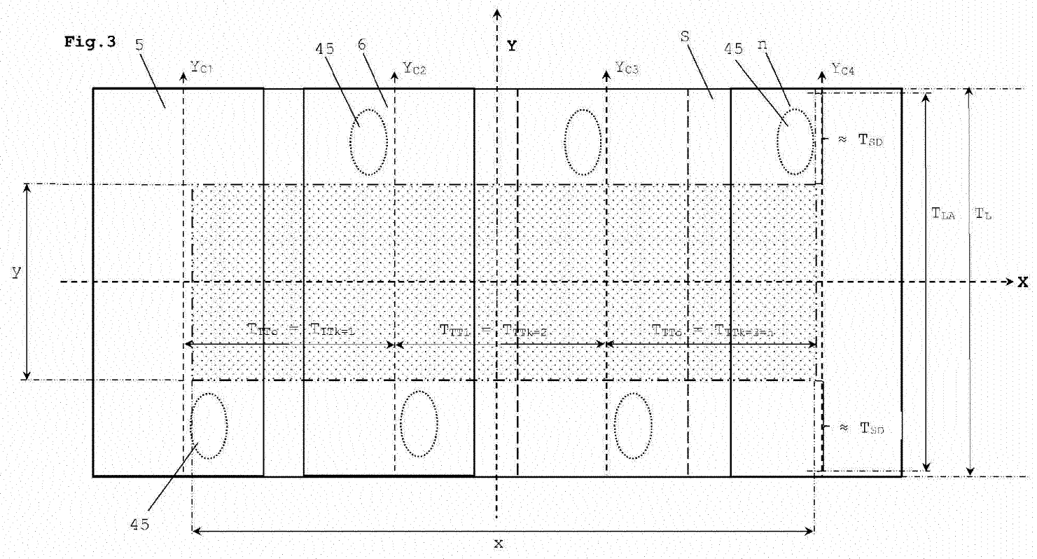

With inner cathode 2 and outer cathode 4 the shaft 33 of the cathode axes Y_{C2},Y_{C4} and transmission spokes 34 are shown, whereas with outer cathode 1 and inner cathode 3 inner and outer swivel planes P_{TSi}, P_{TSo} (dash-pointed lines) and respective inner and outer swivel angles ±βᵢ, ±βₒ (dashed lines) are shown exemplarily. The cathode arrangements 1,2 with magnetic systems 9,10 can be seen as mirrored in the YZ-plane to respective arrangement 3,4 with magnetic systems 11,12. The angle αᵢ of the inner swivel planes P_{TSi} is normal to the substrate plane S, whereas the angle αₒ of the outer swivel planes P_{TSo} are inclined at nearly 45° to the substrate plane S, so that planes P_{TSo} are oblique downward and to the central plane YZ seen from axes Y_{Co}. Where indices “i” and “o” refer to inner and outer cathodes and respective dimensions, angles, swivel planes and the like. The maximum of the magnet swing out of the swivel planes P_{TS} is given by respective angles ±β. Outer swivel angles ±β are about 20°, inner swivel angles ±βᵢ are about 40°, which each can be varied up to the respective process needs. It should be mentioned that for many processes in the semiconductor industry, due to the thin layers, e.g. from some nanometers to about 500 nm, and high process efficiency which means a high cathode power applied, usually one magnet swing between the maximum positions, i.e. from +β position to −β position will suffice to deposit the required layer thickness. The swivel movement can be realized in a constant or a stepwise manner. Speed may vary or hold time may be different with consecutive swivel positions so that dwell time of the magnet system may vary and be different for instance for angle range +β to zero and range zero to −β. As shown with FIG. 1 and FIG. 2 cathode axes Y_{C2}, Y_{C4} of the outer cathodes 1,4 may have an offset of some millimeters, e.g. 5 mm to 60 mm, to the maximum substrate dimensions in an x-direction. Alternatively, as shown with FIG. 3 they may be essentially flush, e.g. within ±10 mm, with the respective y-sides of the maximum substrate dimensions. In each case, axes of the outer cathodes will be symmetrical and in parallel to the center Y-axis.

Cathodes 1,2,3,4 with mounted targets 5,6,7,8 are of the same size, respective of the same diameter D_{T}, arranged in equal distance T_{TT} (i.e. T_{TTi}=T_{TTo}) from each other and in equal distance T_{SD} (i.e. T_{SD1}= . . . =T_{SD4}) or at least in approximately equal distance MT_{SD}−±2 mm from the target plane S. Alternatively, as shown in dotted lines, the position of the outer cathodes 1′, 4′ with targets 5′,8′ can be moved vertically, e.g. lowered as shown, so that the distance T_{SDo′} of the outer targets 1′, 4′ to the target plane is different to the distant T_{SDi} of the inner targets 2,3 to the target plane S. In addition, position of the outer cathodes 1′, 4′ with targets 5′,8′ can be moved sidewise, e.g. towards the middle as shown, so that the distance T_{TTi} between two inner targets is different to the distant T_{TTo} between an outer target to the next inner target. Alternatives as discussed may help to improve layer uniformity parameters like (thickness or specific resistance) in an x-direction, e.g. when length x of the centrally positioned substrate would be shorter than the distance between the two outer axes in an arrangement of equal distances as shown with cathodes 1,2,3,4, or more formally expressed:

$$x < \{ {\sum }_{k = 1}^{n} {T}_{TTk} \} , here x < 3 {T}_{TT} = {T}_{TTi} + 2 {T}_{TTo}$$

for: T_{TT}=T_{TTk=1} . . . =T_{TTn} (here n=3)
and at the same time: T_{SD}≈T_{SDk=1}≈ . . . ≈T_{SDm} (here m =4) and T_{SC}=T_{SCo}=T_{Sci}.

Therefore, an arrangement as shown with dotted cathodes 1′,2′,3′,4′ would allow to adjust the nearest distance of the outer cathodes to the substrate surface to be coated, e.g. to a distance value |T_{SDi}| according to the normal distance T_{SDi} of the inner cathodes 2 and 3. In such case of different target to substrate plane distances, the longer distance has to be used to calculate the minimum value of the target protrusions or to calculate the maximum y-value for the substrate area for a given cathode array. Such an arrangement may be helpful also when the outer cathodes are driven with a different power, e.g. with higher or lower power, or a different power supply like an AC or a DC-supply, see below.

As a counter-pole to the cathodes a ground anode 19 is provided encompassing the cathode array. This can be realized by respective liners or shields, e.g. encompassing and/or forming essentially the whole inner surface of the deposition chamber 31 with the exception of the cathodes 1,2,3,4 and the pedestal 15 for the substrate 14.

The pedestal encompasses further an isolation or an isolated ESC 16 to allow a biased, e.g. RF, grounded or floating substrate potential, up to the respective process needs. A cooling/heating circuit comprising a cooling or heating fluid inlet 17, and a fluid outlet 18 may be provided. Usually water will be used as cooling liquid.

The pedestal may be further provided with a back-gas supply 20 to enhance thermal transfer from the pedestal 15 to a flat substrate 14 mounted to it or vice-versa. A back-gas supply 20 may comprise a gas supply for at least one inert gas, e.g. He and/or Ar and at least one gas inlet 21a leading to the surface of the pedestal 15, e.g. in the surface of the isolated ESC 16. Alternatively, there may be several inlets or gas distribution ducts, e.g. leading from a center towards further outside pedestal or ESC surface areas and having a flow area to transport back-gas with a low flow resistance. The ducts may be in part or even completely open to the backside of the wafer and being connected to shallow but wide gas channels, e.g. from 10 μm to 100 μm, or 50±10 μm depth, having a considerable higher flow resistance than the ducts and covering an essential area of the pedestal/ESC surface to provide an effective thermal transfer between the wafer and the pedestal/ESC surface via the back-gas. Alternatively, the wafer may be positioned on spacers in a close distance above the pedestals or the ESCs surface, e.g. according to the channel depth as mentioned, thereby forming another kind of channel between the wafer and the pedestal/ESC. With both variations the substrate may be further positioned on a surrounding projection, e.g. a gasket to allow a higher back-gas pressure. In a further embodiment the projection may be provided with small outlet openings to the process atmosphere or a back-gas outlet 21b may be provided to lead the back gas directly to the pump socket 22 of the high vacuum pump 23.

Elevation rods 24 allow to move the pedestal in a vertical direction, e.g. to load the substrate 14 to the pedestal in a lowered position (not shown), to close the deposition chamber 31 and/or adjust the substrate to cathode distance in an upper position as shown.

A process gas inlet 36 for inert sputter gases like Argon, Neon and/or Krypton and, if reactive processes should be performed to deposit compounds of the target material, respective reactive gases comprising e.g. nitrogen, carbon, or oxygen, can be connected to a gas distribution system 37 to distribute process gasses evenly in the deposition chamber 31.

In FIG. 2 a system similar to FIG. 1 is shown in a horizontal projection. For same reference numbers it may be referred to FIG. 1. Cathodes 1,2,3,4 have target caps 35 to protect mechanical arrangements like drive gears 26 to move the targets 5,6,7,8 and other feedthroughs and will usually be provided with further target caps 35′, schematically shown with cathode 2 only, both to avoid particle exchange from the hollow target cathodes to the deposition chamber and vice-versa. Additionally caps 35, 35′ may be provided with vacuum gaskets and/or sealings for the target cooling system. As usual, only the target and respective voltage connection of the cathode will be connected to the respective voltage supply 13, whereas other parts of the cathode are isolated from the target and connected to ground.

Attention should be given to the different power supply systems the apparatuses of FIG. 1 and FIG. 2 are provided with. In FIG. 1, cathodes 1 or 1′ and 2, as cathodes 3 and 4 or 4′ are connected with respective two supplies 13 each in a dual magnetron configuration, with each pulse supply 13 providing its symmetric negative and positive signals alternatingly to cathodes 1 (1′) and 2 respectively to cathodes 3 and 4 (4′). A synchronizing unit 38 synchronizes the signals of the respective supplies 13. A typical voltage signal from a dual magnetron supply providing a signal symmetric in signal height and time is shown in FIG. 7.

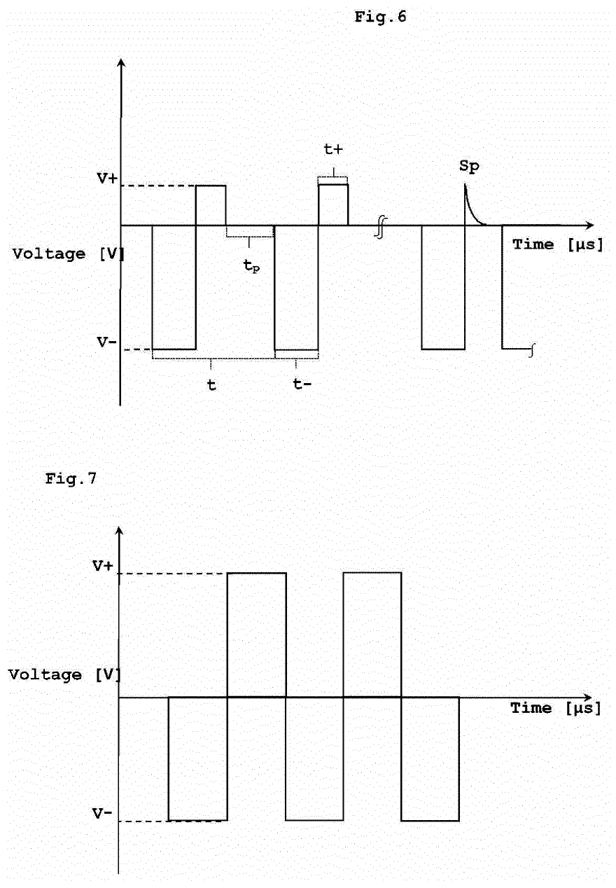

Contrary to that with FIG. 2 each outer cathode 1, 4 and each inner cathode 2, 3 is provided with power supplies 13ₒ and 13ᵢ respectively. In a first embodiment comprising dashed and solid connection lines between the synchronization unit 38 and power supplies, all power supplies 13ₒ and 13ᵢ are pulse power supplies, however, need not fulfill the same signal criteria as dual power pulse supplies. As can be seen with FIG. 6 with such power supplies period time t may have a longer negative time span t− and a shorter positive time span t+ for the respective sub-periods, and height of the positive discharge voltage V+ can be essentially lower than the negative voltage V−. Even a positive spike discharge Sp as exemplarily shown on the right side of the graph may suffice to provide the effect of the invention to minimize the sidewise area of swing induced thickness asymmetries in cathode arrays.

In a further embodiment shown in FIG. 2 including only the solid connection lines between the pulse power supplies 13ᵢ of the inner cathodes 2,3 and synchronization unit 38, outer cathodes 1,4 may be provided with DC-supplies. It has to be understood that the power supply schemes as shown with FIG. 2 can be applied also to the cathode array as shown in FIG. 1, e.g. pulsed power supplies 13ₒ or DC-supplies may be applied to the lowered and/or sidewise in an x-direction shifted outer cathodes 1′,4′ and at least one “inner” pulse power supply 13ᵢ can be connected to the inner cathodes either with a separate supply for every cathode or in a dual magnetron configuration comprising inner cathodes 2 and 3.

In FIG. 2 also the maximal substrate surface dimensions xy and their relation to the target dimensions, e.g. TL, the geometric target length, and T_{LA}, the active target length referring to the target length at which sputtering takes place, are shown. With an ideal cathode design, which is strongly influenced by the type of the magnetic system 9, 10, 11, 12, T_{LA} will equal to TL so that the whole target surface can be sputtered equally. It should be mentioned that only magnetic systems 9 and 11 are shown in FIG. 2 for reasons of clarity. FIG. 3 depicts the substrate plane S only out of FIG. 2 and shows further details like the respective protrusion T_{SD} on both sides of the maximum dimension y of the substrate surface. Further on areas of higher thickness 45 diagonally opposed on both sides of each axis Y_{C1}, Y_{C2}, Y_{C3}, Y_{C4} are shown in a centered plane of dimensions x=x and y=T_{LA}. Areas 45 are provoked by as mentioned swing induced thickness asymmetries during swiveling of the magnetic systems round respective axes.

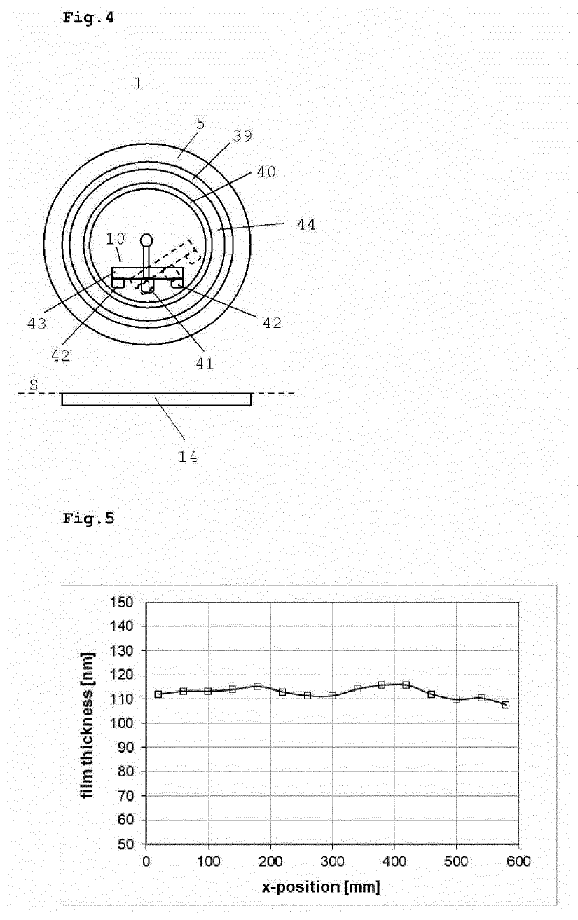

FIG. 4 shows further details of a cathode 1 in a side view with magnetic system 10 in solid lines facing the substrate 14 and in dashed lines swiveled and therewith inclined to the substrate plane S. The magnetic system 10 is swiveled within the inner space of the cooling tube 40 which can be at ambient atmosphere, the latter defining also the inner boarder of the cooling circuit 44 of the sputter target, the outer boarder being defined by a backing tube 39 which also gives mechanically support to the target. Respective vacuum gaskets and/or sealings for the target cooling system may be provided with caps 35, 35′. Target cooling water in- and outlets may be provided axially and be radially distributed, e.g. at opposite cathode ends.

In table 1 the key dimensions of two inventive apparatuses for two different substrate geometries are shown. Both apparatuses are of a modified Clusterline PNL type. For apparatus 1 (Appar.1), which is based on a Clusterline PNL500 model, substrates in the range of 500±15 m×500±15 mm could be coated with a three cathodes array. For apparatus 2 (Appar.2), which is based on a Clusterline PLN600 model, substrates in the range of 600±20 m×600±20 mm could be coated with a four cathodes array.

TABLE 1

| Apparatus Geometry | Unit | Appar. 1 | Appar. 2 |
|---|---|---|---|
| Number of cathodes | 1 | 3 | 4 |
| yₘₐₓ | mm | 500 | 600 |
| 0.5(T_{LA} − yₘₐₓ)/MT_{SD} | 1 | 1.42 | 1.91 |

The formula defines respective target protrusions as used per side of the respective substrates. Targets having a diameter D_{T from} 140 mm to 160 mm have been used. Using such apparatuses, DC-power supplies for state of the art processes and bipolar pulsed DC-power supplies for inventive processes have been used with targets comprising swivel mounted magnetic systems. Parameters as shown in table 2 have been applied to show that swing induced thickness asymmetry could be effectively improved to enlarge the substrate surface in both y directions.

TABLE 2

| Process parameters | Unit | Range 1 | Range 2 |
|---|---|---|---|
| Proc. pressure tot. | mbar | 1E−2-1E−4 | 5E−3-5E−4 |
| Pulsed DC power | W/targ. | 100-10000 | 500-6000 |
| Frequency | kHz | 50-350 | 50-150 |
| Negative Pulse | μs | 2-15 | 5-15 |
| width t− | | | |
| Target material | — | Al, trans. Me* | Al, Cu, Gr. 4-10** |
| MT_{SD} | mm | 60-110 | 70-100 |
| Chuck temperature | ° C. | 20-450 | 50-150 |

*Any transition metal, i.e. group 3 to 12 of the periodic system, or Al, or a combination thereof;
**Any group 4 to 10 element, Al, or Cu, or a combination thereof.

Applying such parameters, coating properties could be reached as shown in table 3.

TABLE 3

| Coating properties: | Unit | Example 1 | Example 2 |
|---|---|---|---|
| Material | Nm | Ti | Cu |
| Thickness | nm | 50-250 | 100-500 |
| Thick. Uniformity, unif_{T} | % | ≤5 | ≤5 |
| Specific resistance R | μOhms*cm | ≤85 | ≤2.6 |
| R uniformity, unif_{R} | % | ≤5 | ≤5 |

With parameters as listed above a thickness distribution as shown in FIG. 5 could be deposited along the central x-coordinate of the substrate normal to cathode axes Y_{Cn} of a 4 cathodes array using Cu-targets. It should be mentioned that in case of a distribution along the X-axis relative thickness variations of coatings deposited by a DC- or a pulsed DC-driven process are about the same, as swing induced thickness asymmetries can be seen in outer y-coordinates of the substrate plane S only. Such deviations along the X-axis have been optimized up-front by an optimization program as commercially available from Sputtering Components Incorporation. An example of such calculations for a four cathodes array is shown in FIG. 8. The cumulative curve of the superposition of the thickness distributions of the four cathodes as shown gives a central uniformity deviation of about ±0.34%. Such optimization when applied to a PNL600 sputtering system resulted in a central uniformity deviation of about ±2% in case of the Cu-layer from FIG. 5. As shown with the four cathode array of FIG. 1 and FIG. 2 the projections of the axes Y_{C1} and Y_{C4} of the outer cathodes are offset outward from the maximum substrate dimensions.

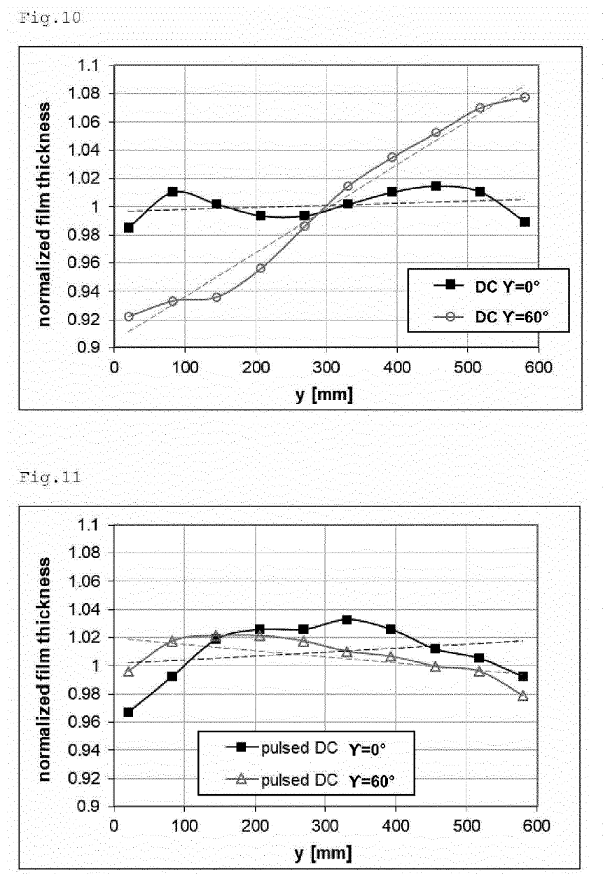

In FIGS. 10 and 11 comparative thickness distributions of two titanium single layers deposited in a Clusterline PNL600 system are shown. For apparatus geometries of PNL600 equipment as used, see table 1, column Appar.2. The thickness distribution was measured along a line with constant x-coordinate in parallel to cathode axes Y_{Cj} and a center axis Y of a 600 m×600 mm substrate surface plane. For these experiments only cathode two of the four cathode array has been used in DC-mode according to a state of the art process, and with a stationary magnetic system in a non-pivoted zero position, in opposition to the substrate plane S, and in a pivoted position with a pivot angle Υ=60° from the zero position of the magnetic system. It should be noted that Υ=0° and Υ=60° refer to respective swivel plane angles α=90° and α=30° towards the substrate plane S and swivel angles β=0°, as with this experiments the magnetic system was used stationary. The distance x has been chosen according to the highest absolute thickness along the X-axis of the substrate surface, which also refers to the highest relative thickness with any other y-value of the same x-coordinate due to the orthogonal arrangement of the cathode axis Y_{Cj} to the X-axis. That maximum thickness value is, in case of a stationary magnetic system at about x=400 mm, the place where the target faces the substrate at normal distance TsD2, the magnetic system being directed towards the substrate.

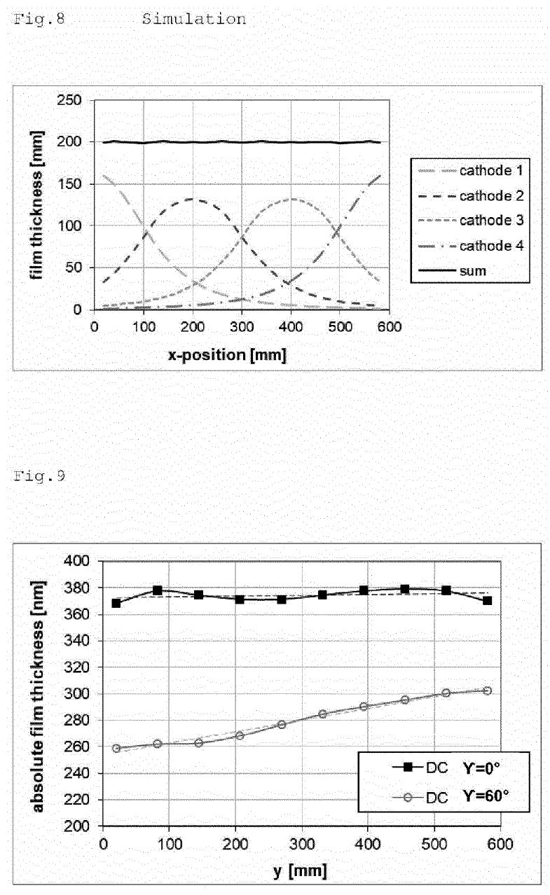

In case of a pivoted magnetic system at Υ=60° from the zero position towards the central ZY-plane, the thickness maximum can be found shifted sidewise towards the center at about 325 mm, the substrates center being at 300 mm. Measuring points for deposition with a magnetic system in zero position are square and denominated DC Υ=0°, measuring points for deposition with a pivoted magnetic system are circular and denominated Υ=60°. A middle thickness of about 375 nm can be calculated from FIG. 9 when the cathode was driven in a stationary mode and a respective thinner middle thickness of about 280 nm could be calculated for the pivoted cathode. However more interesting than the absolute thicknesses as shown in FIG. 9 are relative thicknesses, normalized to the respective middle thicknesses of the two coatings as shown in FIG. 10.

From there a thickness uniformity unif_{T}(Υ=0°)=±1.5% can be deduced for a deposition in the zero position of magnetic system, whereas the thickness uniformity achieved with the pivoted magnetic system was very poor with uniformity unif_{T}(Υ=60°)=±7.8. At the same time the distribution is highly asymmetric being thin at one end and thick at the other end of the y-coordinates. It should be noted again that these measurements were made on one x-coordinate of maximum thickness only. Taking into account a thickness distribution of the whole substrate surface it is clear that despite optimization programs for the thickness distribution along a central x-coordinate, as shown with FIG. 8, thickness non-uniformities along y-coordinates are still a challenge. These results also clearly show the need to provide excessive protrusions over the substrate dimensions with both target ends, e.g. ≥2 T_{SD} at each side, to arrive at an at least somehow acceptable thickness uniformity along the y-coordinates when pivoted or swiveled magnetic systems are used to optimize the thickness distribution along the x-coordinates of a substrate coated statically with an anode array arrangement. It should be mentioned that this effect isn't of a similar importance for inline systems where substrates are moved through zones of different deposition rates whereby thickness differences in x-direction are leveled, and thus the magnets can always stay at α=90° and do not need to be pivoted or swiveled.

In FIG. 11 the results of similar comparative relative thickness distributions of titanium coatings deposited with a stationary magnetic system as with FIG. 10 are shown. In this case however contrary to state of the art processes in FIG. 9 and 10 a bipolar pulsed DC-power supply has been connected to the only powered cathode three of the array. Measuring points for deposition in zero position, here of cathode 3, denominated as pulsed DC Υ=0° are square, measuring points for deposition with a pivoted magnetic system are triangular and denominated pulsed DC Υ=60°. The difference to the DC driven cathode is very surprisingly to the man of art, as the uniformity of the thickness distribution with a magnetic system pivoted by Υ=60° an about 3-fold smaller deviation from the uniformity, namely unif_{T}(Υ=60°)=±2.1, could be attained compared to the respective DC-driven pivoted cathode as shown in FIG. 10. At the same time the symmetry of the distribution is now similar to the distribution of the coatings deposited with a non-pivoted system showing a slightly thicker central region and a respective decease of the coating thickness towards the side areas.

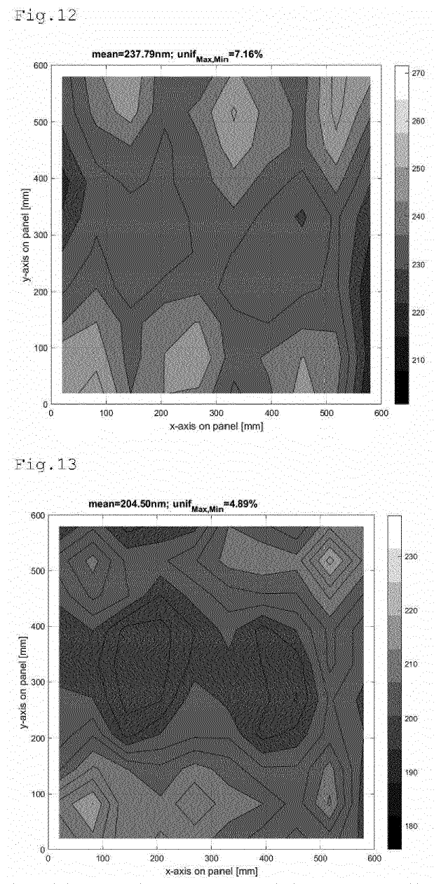

FIG. 12 and FIG. 13 show a surface scan thickness distribution of a coating deposited with a state of the art DC-process respectively with an inventive pulsed-DC process on a PLN600 (appar.2) system as schematically shown in FIG. 1 and FIG. 2 and respective dimensions in table 1. All four cathodes, respectively copper targets were at the same distance T_{SD} from the cathode plane S. Power was supplied by four dedicated DC-supplies for the state of the art process and by four pulsed and synchronized DC-supplies for the inventive process.

The results of surface area measurements of the thickness uniformity on a 600 m×600 mm glass substrate with an edge exclusion of 10 mm for DC sputtering showing distinct swing induced thickness asymmetry is shown in FIG. 12. For practical reasons, with FIG. 12 and 13 the axes origin is in the left lower corner of the substrate. The gray scale is adjusted to show a range of −15% to +15% relative to mean value. The state of the art process in FIG. 12 resulted in a mean thickness of about 238 nm and a uniformity unif_{T}=7.6 within the substrate dimensions as measured. The measurements were performed with a 4-point probe surface resistance Rs measurement device and measured sheet resistance was transferred to film thickness values assuming constant specific resistivity.

The same measurement on a respective glass substrate coated with a pulsed-DC process according to the present invention however resulted in a mean thickness of about 205 nm and a uniformity unif_{T}<5.0 between the minimum and the maximum value, which is more than 30% better than the uniformity of the DC-process. Especially in the side areas between with 200≥y and 400≤y topographic differences are remarkably lowered.

Experimental results as shown with FIG. 9 to FIG. 13 therefore clearly show that thickness-uniformity can be considerably improved by use of bipolar pulsed power supplies whereby substrate surface can be enlarged with a given cathode geometry, or cathode length can be reduced with a given substrate geometry.

### REFERENCE NUMBERS

1 cathode (electrode in case of dual magnetron supply)
2 cathode (electrode in case of dual magnetron supply)
3 cathode (electrode in case of dual magnetron supply)
4 cathode (electrode in case of dual magnetron supply)
5 target
6 target
7 target
8 target
9 magnetic system
10 magnetic system
11 magnetic system
12 magnetic system
13 pulse power supply
13′ power lines
14 substrate
15 pedestal
16 isolation, or isolated ESC (electrostatic chuck)
17 cooling liquid in
18 cooling liquid out
19 anode
20 back-gas supply
21a back-gas inlet
21b back-gas outlet
22 pump channel
23 pump
24 elevation rods
25 target drive
26 drive gear
27 bottom
28 sidewalls
29 top
30 apparatus
31 deposition chamber
32 magnet motor
33 shaft
34 spokes
35 target cap
36 process gas inlet
37 gas distribution system
38 synchronizing unit
39 backing tube
40 cooling tube
41 inner magnets
42 outer magnets
43 magnet yoke
44 cooling circuit
45 area of higher coating thickness
i, o indices i and o refer to inner and outer cathodes and respective dimensions, angles, swivel planes, power supplies . . .
αₒ, αᵢ angle between plane P_{Tso}, P_{TSi} and the vertical
β, βᵢ, βₒ max. swivel angle of (inner/outer) magnet system
C_{L} cathode length
D_{T} target diameter; D_{T} indicates any of the target diameters D_{T1} . . . D_{Tn}, D_{Tmax}, D_{Ti}, or D_{To};
P_{Tso}, P_{TSi} swivel plane for magnets of outer, inner cathode
S substrate plane
Sp electric spike
T_{L} target length
T_{LA} length of an active target surface region
T_{SC} distance cathode axis to substrate plane S; T_{SC} indicates any of the distances T_{SCi} or T_{SCo} which can be equal or different
T_{SD} distance target to substrate plane S; T_{SD} indicates any of the distances T_{SD1} . . . T_{SDn}, T_{SDi}, T_{SDo′}, and MT_{SD} which can be equal or different
MT_{SD} mean distance value MT_{SD}=(T_{SD1}+ . . . +T_{SDn})/n
T_{TT} distance between target axes; T_{TT} indicates any of the distances T_{TTi} or T_{TTo} which can be equal or different
x*y maximal dimensions of the substrate surface
X,Y,Z axes
Y_{cj} longitudinal axis of the cathode; Y_{cj} indicates any of the axes Y_{C1} . . Y_{C4}, Y_{Ci} and Y_{Co};

What is claimed is:

1. An apparatus for sputter deposition of material on a substrate, said apparatus (30) comprising:
a deposition chamber (31);
a cathode array mounted in the deposition chamber, said array having three or more rotating cathodes (1,2,3,4,n), each cathode having a cylindric target (5,6,7,8,n) of equal target length L_{T} and a magnetic system (9,10,11,12,n), the cathodes being spaced from one another such that their longitudinal axes Y_{Cj} are arranged parallel to each other, in a distance Tse from a substrate plane S, and spaced apart along a projection of a substrate axis X in a distance TTT, whereat each cathode of the cathode array comprises a magnetic system (9,10,11,12,n) and the magnetic system (9,12,n) of at least one cathode is swivel mounted round respective cathode axis Y_{Cj} to swivel the magnetic system into and out of a swivel plane P_{TS};
a pedestal (15) designed to support at least one substrate (14) of maximal dimensions x*y to be coated in a static way, the pedestal being positioned in the deposition chamber in front of and centered with reference to the cathode array;
at least one pulsed power supply (13) configured for supplying and controlling a power to at least one of the cathodes.

2. The apparatus of claim 1, whereat the following applies:
(T_{LA}−3.9 MT_{SD})≥yₘₐₓ≥(T_{LA}−2 MT_{SD})
whereat T_{LA} is the length of an active region on the target surface, yₘₐₓ is a maximum substrate dimension parallel to longitudinal axes Y_{Cj}, MT_{SD} is the mean shortest distance between the outer target diameter D_{Tn} and the substrate plane S.

3. The apparatus of claim 2, whereat MT_{SD}≈T_{SD1}≈ . . . ≈T_{SDn}.

4. The apparatus according to claim 1, whereat a distance T_{TT} between the axes of neighboring cathodes is equal for all distances T_{TTK-n} between neighboring cathodes.

5. The apparatus according to claim 1, whereat the cathodes are spaced equidistantly in a normal distance T_{SC} from the substrate plane S.

6. The apparatus according to claim 1, whereat the distance T_{SCo} of at least one or both outer cathodes to the target plane S is different to the distance T_{SCi} of the inner cathodes to the target plane S.

7. The apparatus according to claim 1, whereat for an angle α between swivel plane PTs and the substrate plane S the following applies: 40°≤α≤100°.

8. The apparatus according to claim 1, whereat for a maximum swivel angle β of the at least one swivel mounted magnetic system the following applies: ±0°≤|β⊕≤±80°.

9. The apparatus according to claim 1, whereat the pulsed power supply is a bipolar pulsed power supply.

10. The apparatus according to claim 9, whereat the bipolar power supply is configured as a dual magnetron supply, the outputs of different polarity being electrically connected with the inputs of two neighboring electrodes.

11. The apparatus according to claim 1, comprising at least two pulse power supplies connected to a pulse synchronizing unit.

12. The apparatus according to claim 1, whereat both outer cathodes are connected to DC power supplies.

13. The apparatus according to claim 1, whereat the pedestal is electrically isolated.

14. The apparatus according to claim 13, whereat the pedestal is connected to an RF supply.

15. The apparatus according to claim 1, whereat the pedestal is electrically grounded.

16. The apparatus according to claim 1, comprising a gas distribution system for providing one or more process gases;

17. The apparatus according to claim 1, whereat the anode is a ground anode formed by the process chamber.

18. Process to deposit a coating comprising: the use of providing the apparatus according to claim 1, whereat a substrate is mounted to and positioned with the pedestal in the deposition chamber, a vacuum is applied to the deposition chamber and a process gas is introduced to the chamber, depositing the coating on at least one flat substrate within the dimensions x*y in the target plane S by applying a pulsed target power to at least one cathode of the array.

19. Process according to claim 18, whereat:
(T_{LA}−3.9 MT_{SD})≥yₘₐₓ≥(T_{LA}−2 MT_{SD})
whereat T_{LA} is the length of an active region on the target surface, yₘₐₓ is a maximum substrate dimension parallel to longitudinal axes Y_{Cj}, MT_{SD} is the mean shortest distance between the outer target diameter D_{Tn} and the substrate plane S.

20. Process according to claim 18, whereat a coating thickness uniformity unif_{T}<5% is produced within the substrate dimensions x*y.

21. Process according to claim 18, whereat at least one power supply is a bipolar power supply.

22. Process according to claim 21, whereat two neighboring cathodes are driven by a bipolar pulsed power supply in a dual magnetron configuration with an output of different polarity connected to each neighboring electrode.

23. Process according to claim 18, whereat a Chrome (Cr), copper (Cu), tantalum (Ta), titanium (Ti), tungsten (W), or tungsten titanium (WTi) coating is deposited by sputtering of Cr, Cu, Ta, Ti, W, or WTi targets.

24. Process according to claim 18, whereat the substrate is mounted electrically floating or on an RF potential.

25. Process according to claim 18, whereat the substrate is mounted electrically grounded.

26. The process according to claim 18, wherein the coating has a uniformity unif_{R} of the specific resistance R [Ωm] of unif_{R}<5% within the substrate dimensions x*y.

27. The process according to claim 18, wherein the substrate is manufactured to include the coating having a thickness uniformity unif_{T}≤5% within the substrate dimensions x*y.
